(19) United States
(12) Patent Application Publication
(10) Pub. No.: US 2026/0324311 A1
(43) Pub. Date: Oct. 15, 2026

(54) CYCLIC ETCHING AND DEPOSITION TO CONTROL FILM PROFILE

(71) Applicant: Lam Research Corporation, Fremont, CA (US)

(72) Inventors: Shane TANG, Camas, WA (US); Gopinath BHIMARASETTI, Portland, OR (US)

(21) Appl. No.: 19/483,805

(22) PCT Filed: May 22, 2024
(86) PCT No.: PCT/US2024/030586

§ 371 Date: Nov. 12, 2025

Related U.S. Application Data
(60) Provisional application No. 63/504,261, filed on May 25, 2023.

(51) Int. Cl. H10P 14/60; C23C 16/04; C23C 16/34; C23C 16/455; C23C 16/505; C23C 16/52; H01J 37/32; H10P 14/694

(52) U.S. Cl. CPC H10P 14/6339; C23C 16/045; C23C 16/345; C23C 16/45536; C23C 16/45544; C23C 16/505; C23C 16/52; H01J 37/32082; H01J 37/32449; H10P 14/6336; H10P 14/69433; H01J 2237/3321; H01J 2237/334

(57) ABSTRACT

Examples are disclosed that relate to controlling a growth profile of a silicon-containing film deposited onto features of a substrate. One example provides a method of performing a cyclic chemical vapor deposition (CVD)/etching process to control a profile of a silicon-containing film deposited onto a substrate comprising spaced structures. Each spaced structure comprises a top field and one or more sidewalls. The method comprises performing a plurality of alternating CVD steps and etching steps. Each CVD step comprises depositing a portion of the silicon-containing film onto the spaced structures of the substrate. Each etching step comprises forming a plasma using a gas mixture comprising a halogen-containing etchant to modify the profile of the silicon-containing film.

### BACKGROUND

Electronic device fabrication processes involve many steps of material deposition, patterning, and removal to form integrated circuits on substrates. Various methods can be used to deposit films of materials onto a substrate. As an example, chemical vapor deposition (CVD) involves exposing a substrate to a continuous flow of precursor gases. The precursor gases react to form a film on the substrate.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to controlling a growth profile of a silicon-containing film deposited onto features of a substrate. One example provides a method of performing a cyclic chemical vapor deposition (CVD)/etching process to control a profile of a silicon-containing film deposited onto a substrate comprising spaced structures. Each spaced structure comprises a top field and one or more sidewalls. The method comprises performing a plurality of alternating CVD steps and etching steps. Each CVD step comprises depositing a portion of the silicon-containing film onto the spaced structures of the substrate. Each etching step comprises forming a plasma using a gas mixture comprising a halogen-containing etchant to modify the profile of the silicon-containing film.

In some such examples, each CVD step is a plasma-enhanced CVD (PECVD) step comprising forming a plasma using a gas mixture comprising one or more film precursors and an inert gas to deposit the portion of the silicon-containing film, and the profile comprises vertical growth of the silicon-containing film on the top field of each spaced structure.

In some such examples, forming the plasma comprising the one or more film precursors additionally or alternatively comprises forming a continuous wave plasma.

In some such examples, the one or more film precursors additionally or alternatively comprises a silicon-containing precursor, molecular nitrogen, and molecular hydrogen.

In some such examples, each PECVD step additionally or alternatively is performed at a first pressure of 0.1 to 3 Torr and each etching step is performed at a second pressure, the second pressure being greater than the first pressure.

In some such examples, each etching step additionally or alternatively further comprises reducing a pressure from the second pressure to the first pressure, and flowing the halogen-containing etchant while reducing the pressure.

In some such examples, the controlled profile additionally or alternatively comprises conformal growth on the top field and the one or more sidewalls of each spaced structure.

In some such examples, each CVD step is a PECVD step comprising forming a plasma using a gas mixture comprising one or more film precursors and an inert gas to deposit the portion of the silicon-containing film.

In some such examples, forming the plasma comprising the one or more film precursors additionally or alternatively comprises pulsing the plasma.

In some such examples, the one or more film precursors additionally or alternatively comprises a silicon-containing precursor and ammonia.

In some such examples, each PECVD step additionally or alternatively is performed at a first pressure of 4 Torr to 20 Torr and each etching step is performed at a second pressure, the second pressure being equal to or lesser than the first pressure.

In some such examples, the silicon-containing film additionally or alternatively comprises silicon nitride.

In some such examples, the silicon-containing film additionally or alternatively comprises one of silicon oxide, silicon oxynitride, silicon carbide, silicon oxycarbide, silicon carbonitride, or silicon oxycarbonitride.

Another example provides a plasma enhanced chemical vapor deposition (PECVD) tool. The PECVD tool comprises a processing chamber, a substrate support disposed in the processing chamber, and a radiofrequency power source configured to supply radiofrequency power to form a plasma in the processing chamber. The PECVD tool further comprises flow control hardware configured to control flow of gas from a film precursor source, an inert gas source, and an etchant chemical source into the processing chamber. The PECVD tool further comprises a controller configured to perform a plurality of alternating deposition steps and etching steps. The controller is configured to, in a deposition step, operate the flow control hardware to flow silicon-containing film precursor from the film precursor source and inert gas from the inert gas source into the processing chamber. The controller is further configured to, in the deposition step, operate the radiofrequency power source to form a plasma comprising the silicon-containing film precursor and the inert gas under conditions configured to deposit a silicon-containing film onto spaced structures of a substrate supported by the substrate support, each spaced structure comprising a top field and one or more sidewalls. The controller is further configured to, in an etching step, operate the flow control hardware to flow a halogen-containing etchant chemical from the etchant chemical source into the processing chamber. The controller is further configured to, in the etching step, operate the radiofrequency power source to form a plasma comprising the halogen-containing etchant chemical under conditions configured to etch the silicon-containing film.

In some such examples, the controller is configured to perform an etching step using one or more of a longer duration or a greater partial pressure of the halogen-containing etchant in comparison to an etching step performed previously in the plurality of etching steps.

In some such examples, the controller additionally or alternatively is configured to, during deposition steps, operate the flow control hardware and an exhaust system of the PECVD tool to maintain a pressure of 0.1 to 3 Torr, and operate the radiofrequency plasma source to form a continuous wave plasma to deposit the silicon-containing film with vertical growth on top fields of the spaced structures.

Another example provides a method of performing plasma-enhanced chemical vapor deposition (PECVD) to control vertical growth of a silicon-containing film deposited onto a substrate comprising spaced structures. Each spaced structure comprises a top field and one or more sidewalls. The method comprises performing one or more cycles of alternating deposition steps and etching steps to deposit the silicon-containing film onto the spaced structures of the substrate. Each deposition step comprises forming a plasma using a gas mixture comprising a silicon-containing film precursor, a nitrogen-containing film precursor, hydrogen gas, and an inert gas to deposit the silicon-containing film onto the spaced structure. Each etching step comprising forming a plasma using a gas mixture comprising a halogen-containing etchant to etch the silicon-containing film, thereby growing the silicon-containing film on the top field of each spaced structure at a growth rate that is faster than a growth rate of the silicon-containing film on the one or more sidewalls of each spaced structure.

In some such examples, the method further comprises decreasing a duration of subsequent deposition steps and increasing a duration of subsequent etching steps while performing the plurality of alternating deposition steps and etching steps.

In some such examples, each deposition step additionally or alternatively is performed at a first pressure and each etching step is performed at a second pressure, the second pressure being greater than the first pressure, and each etching step further comprises flowing the halogen-containing etchant while reducing a pressure from the second pressure to the first pressure.

In some such examples, forming the plasma in a subsequent deposition step of the plurality of deposition steps additionally or alternatively comprises forming a plasma further comprising residual halogen-containing etchant from a prior etching step.

### BRIEF DESCRIPTION OF THE DRAWINGS

FIGS. 1A-1G schematically show example vertical growth of a film on a top field of spaced structures using alternating deposition steps and etching steps.

FIG. 2 schematically shows a concentration gradient of an adsorbed halogen-containing etchant on spaced structures of a substrate.

FIG. 3 shows a flow diagram of example cyclic CVD/etching process comprising alternating deposition steps and etching steps.

FIGS. 4A-4G schematically show an example of conformal growth of a film on spaced structures using alternating deposition steps and etching steps.

FIG. 5 shows a flow diagram of an example cyclic CVD/etching process comprising alternating long duration deposition steps and long duration etching steps followed by alternating short duration deposition steps and short duration etching steps.

FIGS. 6A-6B show a flow diagram of an example method for performing cyclic CVD/etching to control a profile of a silicon-containing film deposited onto spaced structures.

FIG. 7 schematically shows an example PECVD tool.

FIG. 8 shows a block diagram of an example computing device.

### DETAILED DESCRIPTION

The term “chemical vapor deposition (CVD)” generally represents a process in which a solid phase film is formed on a substrate by directing a continuous flow of one or more precursor gases over the substrate surface under conditions configured to cause the film formation. Plasma enhanced chemical vapor deposition (PECVD) utilizes a plasma to facilitate the film formation.

The term “conformal film” generally represents a film having a consistent thickness on substrate surfaces of different orientations.

The term “deposition step” generally represents part of a cyclic PECVD/etching process in which a film is deposited on a substrate.

The term “etching step” generally represents part of a cyclic PECVD/etching process in which a portion of a film that was deposited in a deposition step is removed to change a profile of the film.

The term “flow control hardware” generally represents components that fluidly connect one or more chemical sources with a processing chamber. Flow control hardware can comprise conduits, mass flow controllers, and/or valves, for example.

The term “gap” generally represents a recess in a substrate surface.

The term “halogen-containing etchant” generally represents a chemical that is used in an etching process to chemically remove or facilitate chemical removal of material from a substrate. Examples include fluorine-containing etchant, chlorine-containing etchants, and bromine-containing etchants. Example fluorine-containing etchants include F₂, HF, BF₃, PF₃, NF₃, chlorofluorocarbons, fluorocarbons, hydrofluorocarbons, chalcogen fluorides such as SF₄ or SF₆, and interhalogens such as ClF₃ and ClF₅. Example fluorocarbons include CF₄ and C₂F₆. Examples of chlorine-containing etchants include HCl, Cl₂, and chalcogen chlorides such as S₂Cl₂ or SCl₂. Examples of bromine-containing etchants include HBr and Br₂. The term “interhalogen” generally represents a molecule comprising two or more different halogen atoms.

The term “cyclic CVD/etching process” generally represents a process comprising one or more cycles, each cycle containing a CVD step and an etching step.

The term “plasma” generally represents a gas comprising cations and free electrons. The term “capacitively coupled plasma” generally represents a plasma formed between capacitive electrode plates. Example capacitive plates can include a showerhead electrode and a pedestal electrode. The term “inductively coupled plasma” generally represents a plasma formed by an electric field created by an inductive coil.

The term “processing chamber” generally represents an enclosure in which chemical and/or physical processes are performed on substrates. The pressure, temperature and atmospheric composition within a processing chamber are controllable to perform chemical and/or physical processes.

The term “processing tool” generally represents a machine comprising a processing chamber and other hardware configured to perform substrate processing.

The terms “purge” and variants thereof generally represent processes in which unwanted species are removed from a processing chamber.

The term “silicon-containing film” generally represents a layer of material that contains silicon and that is positioned on an underlying substrate. A silicon-containing film can be deposited using CVD. Example silicon-containing films include films comprising silicon nitride, silicon oxide, silicon carbide, silicon oxycarbides, silicon oxynitrides, silicon carbonitride, and silicon oxycarbonitride.

The term “silicon-containing precursor” generally represents any material that can be introduced into a processing chamber in a gas phase to form a silicon-containing film on a substrate. Example film precursors for forming silicon-containing films using CVD can comprise materials having the general structure:

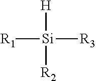

where R₁, R₂ and R₃ can be the same or different substituents. In various examples, R₁, R₂, and R₃ can include silanes, amines, halides, hydrogen, or organic groups such as alkylamines, alkyl, alkenyl, alkynyl, and cyclic groups (such as aromatic groups).

In some examples, the silicon-containing precursor is an alkoxysilane. Alkoxysilanes that can be used include compounds having a general formula of Hₓ—Si—(OR)_{y}, where x=1 to 3, x+y=4 and each R is a substituted or unsubstituted aliphatic or aromatic group; and Hₓ(RO)_{y}—Si—Si—(OR)_{y}Hₓ, where each R is a substituted or unsubstituted aliphatic or aromatic group. Example alkoxysilanes include tetramethoxysilane (TMOS), diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor is a siloxane. Siloxanes include materials having Si—O—Si linkages. Example siloxanes include octamethylcyclotetrasiloxane (OMCTS), octamethoxydodecasiloxane (OMODDS), and tetramethylcyclotetrasiloxane (TMCTS).

In some examples, the silicon-containing precursor is an aminosilane. Aminosilanes include materials having a general formula Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group. Example aminosilanes include bisdiethylaminosilane, diisopropylaminosilane, bis(t-butylamino) silane (BTBAS), di-sec-butylaminosilane, and tris(dimethylamino) silane (3DMAS).

In some examples, the silicon-containing precursor is a halogen-containing silane. A halogen-containing silane can be referred to as a halosilane. In some examples, a halosilane can comprise at least one hydrogen atom. Such a silane can have a general formula of SiXₐH_{y} where y≥1. Example halosilanes include dichlorosilane (H₂SiCl₂), hexachlorodisilane (Si₂Cl₆), and diiodosilane (H₂SiI₂).

More specific examples of silicon-containing precursors include silane (SiH₄) and polysilanes ((SinH₂ₙ₊₂, where n≥1, such as disilane, trisilane, and tetrasilane), trisilylamine, tetraethyl orthosilicate (TEOS), methylsilane, trimethylsilane (3MS), ethylsilane, butasilanes, pentasilanes, octasilanes, heptasilanes, hexasilanes, cyclobutasilane, cycloheptasilane, cyclohexasilane, cyclooctasilane, cyclopentasilane, 1,4-dioxa-2,3,5,6-tetrasilacyclohexane, triethoxysiloxane (TRIES), and tetraoxymethylcyclotetrasiloxane (TOMCTS).

Example carbon-containing precursors for forming silicon carbide and other silicon-containing films that comprise carbon can include alkanes, alkenes, alkynes, cyclic hydrocarbons, aromatics, alkyl halides, alkyl amines, and alkyl diamines. In some examples, the carbon-containing precursor can comprise an alkane comprising a general formula CₙH₂ₙ₊₂ in which n=1 to 10. Examples of suitable alkanes can include methane, ethane, propane, butane, pentane, hexane, and substituted alkanes. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutene, cyclopentane and cyclohexane. Examples of suitable aromatics can include benzene, toluene, pyridine, and pyrimidine. Examples of suitable alkyl halides can include ethyl fluoride, isopropyl bromide, and t-butyl chloride. Examples of suitable alkyl amines can include methylamine, dimethylamine, trimethylamine, and piperidine. Examples of suitable alkyl diamines can include ethylenediamine and 1,3-diaminopropane. In still other examples, the carbon-containing precursor can include a mixture of carbon-containing precursors.

Example nitrogen-containing precursors for forming silicon nitride films can include ammonia (NH₃) and amino silanes. Examples of amino silanes include those listed above.

An example precursor for providing nitrogen for formation of a silicon oxynitride film is N₂O.

The term “spaced structures” generally represents features on a substrate that are recessed into, or that extend from, a surrounding substrate surface, and that are spaced from one another.

The term “substrate” generally represents any object on which a film can be deposited.

The term “showerhead” generally represents a processing gas outlet for that includes a plurality of spatially-distributed outlet holes for directing processing gases across a substrate surface.

The term “substrate support” generally represents any structure for supporting a substrate in a processing chamber during substrate processing. An example substrate support is a pedestal.

The term “sidewall” generally represents a surface of a spaced structure that extends at least partly upwardly or downwardly from a surface plane of a substrate.

The term “top field” generally represents a highest portion of a substrate feature. A top field can have a generally planar configuration in some examples. Example top fields include a top surface of a pillar and a substrate top surface between gaps.

As discussed above, electronic device fabrication can include deposition processes and etching processes to form structures on a substrate. For example, an etching process may be performed to remove material from within gaps. To avoid damaging the top field between adjacent gaps, a patterned hardmask can be formed on the top field regions. However, forming a patterned hardmask can involve time-consuming photolithographic patterning processes. An example hardmask fabrication process can first involve deposition of a hardmask layer. Example hardmask layers can include silicon nitride, silicon oxide, silicon carbide, silicon oxynitride, silicon oxycarbide, silicon carbonitride, and silicon oxycarbonitride. The hardmask formation process can further involve deposition of a photoresist layer over the hardmask layer. The photoresist layer is then exposed and developed. Next, an initial etching step is performed to remove regions of the hardmask that are not protected by the photoresist. This forms the patterned hardmask. Next, residual photoresist is removed. Then, etching can be performed on the gaps. The patterned hardmask protects the top field regions between the gaps during the etching. Finally, the patterned hardmask is removed. Such a hardmask fabrication and process can add substantial time and cost to substrate processing.

Deposition of a conformal film onto spaced structures also can be challenging. Atomic layer deposition (ALD) can be used to form a conformal film on a substrate in a layer-by-layer manner using one or more ALD cycles. In an ALD cycle, a film precursor gas is adsorbed onto a surface of a substrate disposed in a processing chamber. Excess film precursor is purged from the processing chamber. Then, the adsorbed film precursor is chemically converted into a film on the substrate. Then, another purge is performed before introducing more film precursor to the processing chamber. A highly conformal film of a target thickness can be grown using one or more deposition cycles. However, as each ALD cycle deposits a thin layer of film, ALD can be relatively slow. ALD processing can comprise 10 s to 100 s of ALD cycles to grow a film. Faster deposition techniques, such as CVD, tend to grow non-conformal films. More particularly, CVD tends to deposit thicker films at a top of a recessed feature than at a bottom of a recessed feature. As such, CVD films can form breadloaf-type profiles as a function of depth on top fields of spaced structures. Further, the CVD films may be thinner at locations deeper within recessed features than at an opening of a recessed feature. This can lead to void formation as film growth near the top of the feature can close off the opening.

Accordingly, examples are disclosed that relate to utilizing cyclic CVD/etching processes to control a profile of a silicon-containing film deposited by CVD on spaced structures. The spaced structures can comprise recessed features and/or protruding features. Each spaced structure comprises a top field and one or more sidewalls. Each deposition step of a CVD/etching cycle forms a layer of a silicon-containing film on the spaced structures. As described above, CVD tends to form films that are non-conformal, with a breadloaf profile at a top of a spaced structure. Thus, each etching cycle is used to modify a profile of the silicon-containing film. Further, as described in more detail below, an etching gas mixture can comprise one or more processing gases that have an inhibiting effect on a next deposition step. Etching conditions can be controlled to modify this inhibition effect by controlling a concentration profile of the inhibiting molecule on the substrate surfaces, particularly on sidewall surfaces of spaced structures. Depending upon conditions employed, the cyclic deposition and etching can provide for vertical growth on top fields of spaced structures, or conformal growth on all surfaces of the spaced structures. Further, the cyclic CVD/etching process can be performed using less expensive precursors (e.g., silane) compared to ALD. As such, the disclosed examples can provide cost-savings in conformal deposition of silicon-containing films. Processing conditions that can be controlled to achieve a desired silicon-containing film profile can comprise a substrate temperature, a total pressure in the processing chamber, a partial pressure of each of one or more gases, a rate of gas flow, a duration of gas flow, a duration of a deposition step, and/or a duration of an etching step.

To achieve vertical growth of a silicon-containing film on the top field of each spaced structure, a capacitively coupled plasma can be used to deposit the silicon-containing film using PECVD. As discussed in more detail below, performing PECVD at a relatively lower total pressure can help achieve a relatively higher degree of vertical growth compared to performing PECVD at a relatively higher total pressure. This is due to ionized precursor molecules undergoing fewer collisions in the path to the substrate surface as a function of decreasing total pressure. This results in more deposition in a vertical direction. Use of a relatively heavy inert gas in the PECVD process (e.g. argon as opposed to helium) also can help achieve vertical growth. This is because the inert gas atoms can sputter the silicon-containing film as the silicon-containing film grows. Because film growth rates are higher in a vertical direction than in a horizontal direction in the relatively lower pressure environment, sputtering of lower growth rate surfaces (e.g. sidewalls of the spaced features) can suppress growth on those surfaces. In contrast, the higher growth rate surfaces can have film growth that more strongly outpaces the etching effect of the inert gas atoms. This can result in greater net vertical growth. Additional profile shaping can then be performed in the etching step performed after the deposition step. Further, a halogen-containing etchant can be used in the etching step. At least some residual halogen-containing etchant can remain in the processing chamber at the start of a deposition step. This can provide an inhibiting effect that inhibits deposition. This can further decrease film growth on sidewalls, in view of the lower film deposition rate on sidewalls than on the top field regions. Further, hydrogen gas can be used in a PECVD step to achieve additional inhibition effects. This can further help to avoid growth of a silicon-containing film on sidewalls of spaced structures.

Vertical growth of a silicon-containing film as disclosed herein can be used to form a hardmask without photolithographic patterning. In some such examples, the silicon-containing film can be grown vertically on a hardmask partway through an etching process. This can allow the use of a thinner initial hardmask layer. The use of a thinner initial hardmask layer can provide for more accurate pattern transfer than the use of a thicker initial hardmask layer. Further, the vertical growth of a silicon-containing film as disclosed herein also can avoid the time and expense of performing photolithography processes to pattern the hardmask.

Cyclic CVD/etching processes also can be controlled to grow a conformal silicon-containing film on the spaced structures. In such examples, deposition steps of the cyclic CVD/etching process can be performed using any suitable CVD method for depositing a silicon-containing film. Examples include thermal CVD and PECVD. Further, deposition steps can be performed using a relatively higher total pressure during CVD than that used for vertical growth. For example, in a PECVD step, the use of a higher pressure reduces the directional etching effects of an inert gas. In some examples, a PECVD step can comprise pulsing the plasma. Pulsing the plasma results in relatively lower ion energies compared to continuous wave plasma. Due to lower ion energies, there may be a greater distribution of ion impact angles on sidewall surfaces. As a result, a relatively greater amount of film-forming species can deposit onto the sidewall surfaces compared to a continuous wave plasma. This helps grow a thicker silicon-containing film on sidewall surfaces. Lower ion energies also can lead to less sidewall sputtering Additionally, sidewall etching can be further reduced by pulsing the plasma during deposition steps. Further, ammonia can be used instead of hydrogen during PECVD. This can help reduce inhibition of film growth on sidewalls compared to the use of hydrogen. By increasing sidewall deposition rates and reducing sidewall inhibition and etching effects, such processing conditions can help achieve conformal growth of the silicon-containing film.

Still, film growth on upper sidewall surfaces and top fields of spaced structures can be faster compared to film growth on other surfaces. However, etching steps can remove material from such upper sidewall and top field surfaces to produce more conformal films. This is because reactive ions in the plasma preferentially adsorb to and etch upper sidewall surfaces and top fields during etching steps of the cyclic CVD/etching process. For example, forming a capacitively coupled plasma using NF₃ forms F ions with top-down velocities (velocities perpendicular to the substrate). Upon contact with substrate surfaces, the F ions quickly react to etch the silicon-containing film. Due to the top-down velocities, the F ions are more likely to strike top fields compared to sidewall surfaces. Additionally, the F ions are more reactive compared to F radicals. As such, F ions can react and/or decay before reaching surfaces lower in gaps. Thus, the F ions preferentially etch surfaces near the top of the spaced structure. By preferentially etching surfaces where there is faster film growth, a cyclic CVD/etching process can be used to grow a silicon-containing film with a relatively high degree of conformality.

While discussed in the context of silicon nitride films, the example cyclic CVD/etching processes disclose herein also can be applied to other films, such as silicon oxide films, silicon carbide films, silicon oxycarbide films, silicon oxynitride films, silicon carbonitride films, and silicon oxycarbonitride films.

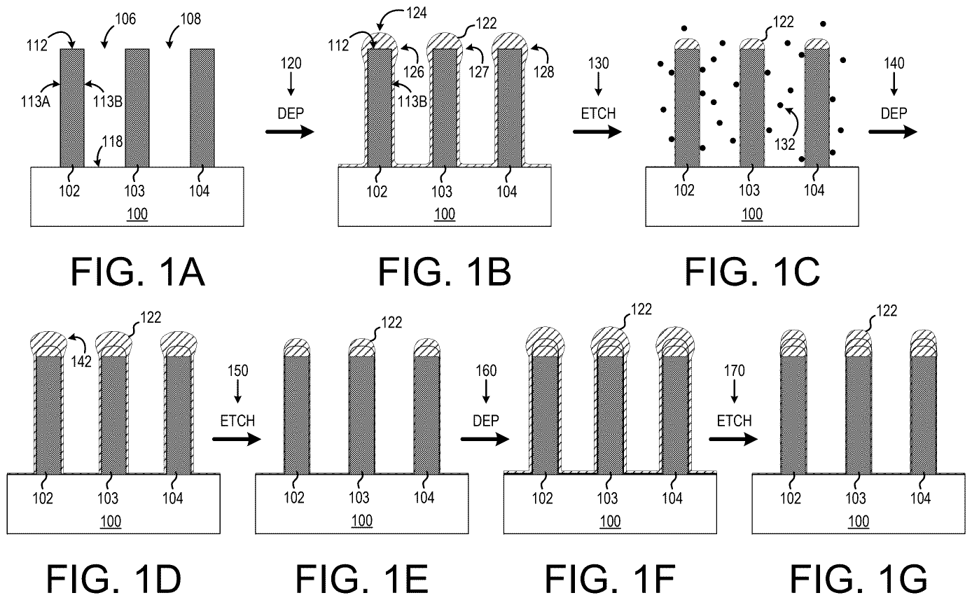

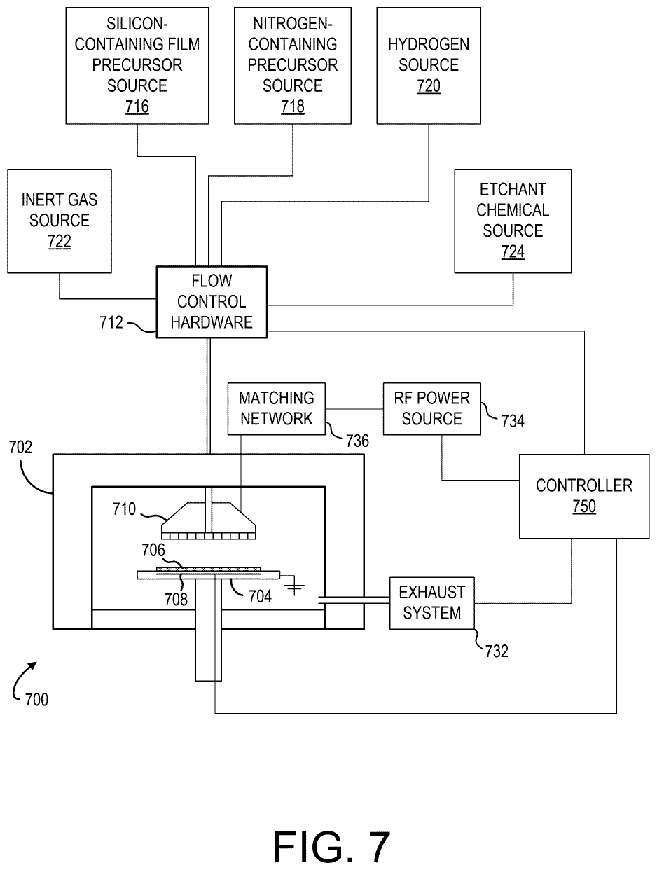

FIGS. 1A-1G schematically show example structures formed during a cyclic CVD/etching process to achieve vertical growth of a film on top field regions of spaced structures of a substrate 100. The cyclic CVD/etching process uses alternating deposition steps and etching steps to deposit the film. In the example depicted in FIGS. 1A-1G, the growth profile comprises vertical growth on top fields of the spaced structures with little film growth on sidewalls of the spaced structures. The cyclic CVD/etching process can be performed in a processing chamber of a processing tool, for example. An example processing tool is described below with regard to FIG. 7.

FIG. 1A shows a substrate 100 comprising three pillars 102, 103, 104. A gap 106 is between pillar 102 and pillar 103. Another gap 108 is between pillar 103 and pillar 104. Each pillar comprises a top field and sidewalls. For example, pillar 102 comprises a top field 112 and sidewalls 113A, 113B. A bottom field 118 is located at the bottom of gap 106 between pillars 102, 103.

FIG. 1B shows substrate 100 following a first deposition step 120 that deposits a portion of a silicon-containing film 122. First deposition step 120 deposits silicon-containing film 122 with vertical growth on top fields of the spaced structures. For example, as indicated at 124, the deposited film is thicker on top field 112 compared to film growth on sidewall 113B and on bottom field 118. The silicon-containing film 122 also is thicker near the top of the sidewalls. This forms so-called “breadloaf” structures 126, 127, 128 respectively on pillars 102, 103, 104.

Where a silicon nitride film is being deposited, first deposition step 120 can comprise forming a plasma using a gas mixture comprising a silicon-containing film precursor, molecular nitrogen (N₂), molecular hydrogen (H₂), and an inert gas. The use of molecular hydrogen gas in the processing gas mixture can reduce the amount of silicon incorporated into the film and improve stability of the film. The hydrogen also can reduce growth rates due to an inhibiting effect, as described in more detail below. One example of a silicon-containing film precursor is silane. In particular, the use of silane can provide cost-savings compared to more expensive precursors used in some ALD processes.

Other examples of silicon-containing film precursors include alkoxysilanes. Alkoxysilanes that can be used include compounds having a general formula of Hₓ—Si—(OR)_{y}, where x=1 to 3, x+y=4 and each R is a substituted or unsubstituted aliphatic or aromatic group; and Hₓ(RO)_{y}—Si—Si—(OR)_{y}Hₓ, where each R is a substituted or unsubstituted aliphatic or aromatic group. Example alkoxysilanes include tetramethoxysilane (TMOS), diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

Further examples of silicon-containing precursors include siloxanes. Siloxanes include materials having Si—O—Si linkages. Example siloxanes include octamethylcyclotetrasiloxane (OMCTS), octamethoxydodecasiloxane (OMODDS), and tetramethylcyclotetrasiloxane (TMCTS).

Other silicon-containing precursors include aminosilanes. Aminosilanes include materials having a general formula Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group. Example aminosilanes include bisdiethylaminosilane, diisopropylaminosilane, bis(t-butylamino) silane (BTBAS), di-sec-butylaminosilane, and tris(dimethylamino) silane (3DMAS).

Further examples of silicon-containing precursors include halosilanes. In some examples, a halosilane can comprise at least one hydrogen atom. Such a silane can have a general formula of SiXₐH_{y} where y≥1. Example halosilanes include dichlorosilane (H₂SiCl₂), hexachlorodisilane (Si₂Cl₆), and diiodosilane (H₂SiI₂).

Yet further examples of silicon-containing precursors include polysilanes ((SinH₂ₙ₊₂, where n≥1, such as disilane, trisilane, and tetrasilane), trisilylamine, tetraethyl orthosilicate (TEOS), methylsilane, trimethylsilane (3 MS), ethylsilane, butasilanes, pentasilanes, octasilanes, heptasilanes, hexasilanes, cyclobutasilane, cycloheptasilane, cyclohexasilane, cyclooctasilane, cyclopentasilane, 1,4-dioxa-2,3,5,6-tetrasilacyclohexane, triethoxysiloxane (TRIES), and tetraoxymethylcyclotetrasiloxane (TOMCTS).

Examples of suitable inert gases include argon, helium, neon, krypton, and xenon. The use of a relatively heavier inert gas such as Ar can help sputter sidewall portions of the pillars 102, 103, 104 and reduce a growth rate of the silicon-containing film 122 on such surfaces compared to the use of helium. This can help achieve a vertical growth profile.

As mentioned above, in some examples, a silicon-containing film includes carbon. Examples of such silicon-containing films include silicon carbide, silicon oxycarbide, silicon carbonitride, and silicon oxycarbonitride. Examples of carbon-containing precursors for forming such films include alkanes, alkenes, alkynes, cyclic hydrocarbons, aromatics, alkyl halides, alkyl amines, and alkyl diamines. In some examples, the carbon-containing precursor can comprise an alkane comprising a general formula CₙH₂ₙ₊₂ in which n=1 to 10. Examples of suitable alkanes can include methane, ethane, propane, butane, pentane, hexane, and substituted alkanes. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutene, cyclopentane and cyclohexane. Examples of suitable aromatics can include benzene, toluene, pyridine, and pyrimidine. Examples of suitable alkyl halides can include ethyl fluoride, isopropyl bromide, and t-butyl chloride. Examples of suitable alkyl amines can include methylamine, dimethylamine, trimethylamine, and piperidine. Examples of suitable alkyl diamines can include ethylenediamine and 1,3-diaminopropane. In still other examples, the carbon-containing precursor can include a mixture of carbon-containing precursors.

Oxygen-containing precursors for forming silicon oxide, silicon oxynitride, silicon oxycarbide, and silicon oxycarbonitride films can include molecular oxygen, water, hydrogen peroxide, and nitrogen oxides (e.g. nitrous oxide).

First deposition step 120 can comprise any suitable duration. In some examples, first deposition step 120 comprises a duration of 2-20 seconds. In other examples, durations outside of this range also can be used. All ranges stated herein are inclusive of the endpoints.

In some examples, the plasma can be formed using a continuous wave plasma. Continuous wave plasmas refer to plasmas formed without modulating radiofrequency power. In other examples, a pulsed plasma can be used. Pulsed plasma can favor conformal film growth over vertical growth. This is because, as described above, the relatively lower ion energies result in a greater distribution of ion impact angles on sidewall surfaces. As a result, a relatively greater amount of film-forming species deposit onto the sidewall surfaces compared to a continuous wave plasma. This helps grow a thicker silicon-containing film on sidewall surfaces. Additionally, the relatively lower energy of inert gas ions in pulsed plasmas can have a lesser sputtering effect on sidewall surfaces compared to continuous wave plasmas. Any suitable radiofrequency power can be used. Examples include radiofrequency power of 50 W to 6500 W. Example frequencies for the radiofrequency plasma include frequencies of 400 kHz, 13.56 MHz, 27 MHz, 60 MHz, and 90 MHz. In some examples, two or more frequencies may be used simultaneously to form a plasma, as described in more detail below. In some examples, a capacitively coupled plasma can be formed by applying RF energy to one of a showerhead or pedestal of a processing tool, wherein the other of the showerhead or pedestal acts as a counter electrode. The use of a capacitively coupled plasma can allow a directionality of film growth to be controlled somewhat by controlling a sputtering of the growing film from an inert gas (e.g. argon) in a processing gas mixture. In other examples, an inductively coupled plasma can be used.

First deposition step 120 can be performed at any suitable substrate temperature and processing chamber pressure. Examples include temperatures of 50° C. to 650° C. and pressures of 0.1 to 3 Torr. Use of a relatively lower pressure can enhance the sputter effect that inert gas ions have on sputtering the silicon-containing film deposited on sidewall portions of the pillars 102, 103, 104. As described above, this can help achieve a faster film growth rate on top fields of the pillars 102, 103, 104 than on the sidewalls of the pillars 102, 103, 104. As such, a film with a vertical growth profile is deposited.

Flow control hardware can be used to control a flow rate and/or quantity of each gas flowing into the processing chamber. In examples in which a silicon nitride film is formed, the silicon-containing precursor can be flowed at a rate of 5-50 standard cubic centimeters per minute (sccm). In some such examples, N₂ can be flowed at a rate of 1000-5000 sccm. In some such examples, H₂ can be flowed at a rate of 100-2500 sccm. Further, in some such examples, the inert gas can be flowed at a rate of 1000-10000 sccm. In other examples, other flow rates can be used. Flow rates can depend upon various factors such as pressure, temperature, and chamber size. Example deposition steps are described in more detail below.

As mentioned above, breadloaf structures can be formed during the first deposition step 120. Thus, the cyclic CVD/etching process next comprises a first etching step 130. FIG. 1C shows substrate 100 following first etching step 130. First etching step 130 comprises forming a plasma using a gas mixture comprising a halogen-containing etchant 132. This forms halide ions from the halogen-containing etchant 132. The plasma modifies the profile of the silicon-containing film 122 by etching the breadloaf structures 126, 127, 128 of the silicon-containing film. Other portions of the silicon-containing film also are etched. For example, some of the silicon-containing film 122 on the top fields and sidewalls of the pillars 102, 103, 104 are etched. As shown in FIG. 1C, the sidewalls of pillars 102, 103, 104 comprise a thinner silicon-containing film 122 compared to the silicon-containing film 122 of FIG. 1B. In some examples, the silicon-containing film can be removed from the sidewalls. However, a portion of silicon-containing film 122 remains on the top fields of pillars 102, 103, 104. As a result, the silicon-containing film 122 comprises a vertical growth profile.

First etching step 130 can utilize any suitable halogen-containing etchant 132. Examples include fluorine-containing etchants, chlorine-containing etchants, and bromine-containing etchants. Example fluorine-containing etchants can include F₂, HF, BF₃, PF₃, NF₃, chlorofluorocarbons, fluorocarbons, hydrofluorocarbons, chalcogen fluorides such as SF₄ or SF₆, and interhalogens such as ClF₃ or ClF₅. Example fluorocarbons include CF₄ and C₂F₆. Examples of chlorine-containing etchants include HCl, Cl₂, and chalcogen chlorides such as S₂Cl₂ or SCl₂. Examples of bromine-containing etchants include HBr and Br₂. The term “interhalogen” generally represents a molecule comprising two or more different halogen atoms.

First etching step 130 can be performed for any suitable duration. Examples include durations of 2 to 10 seconds. In other examples, an etching step duration outside of this range also can be used. Flow control hardware can be used to control a flow rate and/or quantity of the halogen-containing etchant flowing into the processing chamber during first etching step 130. In some examples, first etching step 130 flows halogen-containing etchant 132 with a flow rate of 100-300 sccm. Additionally, an inert gas can be flowed at a rate of 5000-30000 sccm. In other examples, flow rates outside these ranges can be used. Further, the first etching step 130 can be performed at a pressure of 3-5 Torr. As such, the first etching step 130 is performed at a higher pressure compared to the first deposition step 120 in some examples.

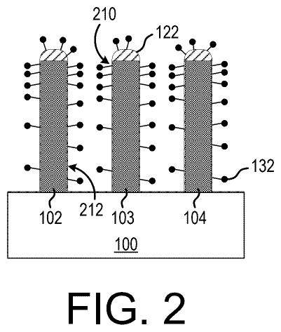

After forming the plasma in first etching step 130, the processing chamber can be purged. In some examples, a partial purge is performed to leave some residual halogen-containing etchant in the processing chamber. The residual halogen-containing etchant has an inhibition effect on a subsequent deposition step. Halogen-containing etchant can adsorb onto sidewalls with a concentration gradient due to the capacitively coupled plasma used in the next deposition step. FIG. 2 schematically shows an example of adsorbed halogen-containing etchant 132 on pillars 102, 103, 104. As shown in FIG. 2, the concentration of halogen-containing etchant 132 adsorbed at upper sidewalls 210 is greater than a concentration at lower sidewalls 212. This can inhibit growth of the silicon-containing film near upper sidewalls 210. Such inhibition can reduce the horizontal film growth that leads to breadloaf structures.

The concentration gradient of the etchant along the sidewalls of the pillars 102, 103, 104 can be controlled by controlling various processing conditions. Example processing conditions include total processing chamber pressure, partial pressure of the etchant, partial pressure of other gases (for example, a diluent gas), substrate temperature, gas flow rates, etchant gas flow duration, and plasma characteristics. For example, the use of a capacitively coupled plasma to etch silicon-containing film 122 can cause directional effects that drive the etchant into a gap. In some examples, the capacitively coupled plasma can comprise a higher frequency radiofrequency energy component (“HF component”) and a lower frequency radiofrequency energy component (“LF component”). In some examples, the HF component can comprise a power of 50-6500 W. Increasing the power of the higher frequency component can drive the halogen-containing etchant farther within the gap. Further, in some examples, the LF component also can comprise a power of 0-6500 W. The use of the LF component can help drive the halogen-containing etchant father within the gap. Increasing the power of the LF component can drive the halogen-containing etchant yet farther within the gap. Thus, the LF component can be adjusted to help remove deposited film from deeper locations on the sidewalls. Further, the LF component can allow control over surfaces on which adsorbed halogen acts as an inhibitor in a next deposition step.

In addition to, or alternatively to, leaving residual halogen-containing etchant 132 in the processing chamber after purging, halogen-containing etchant 132 can be flowed into the processing chamber following a purge. For example, halogen-containing etchant 132 can be flowed for a duration of 1-3 seconds. As mentioned above, the deposition step can be performed at a first pressure and the etching step can be performed at a second pressure that is higher than the first pressure. In some such examples, the halogen-containing etchant can be flowed while reducing the pressure from the second pressure to the first pressure.

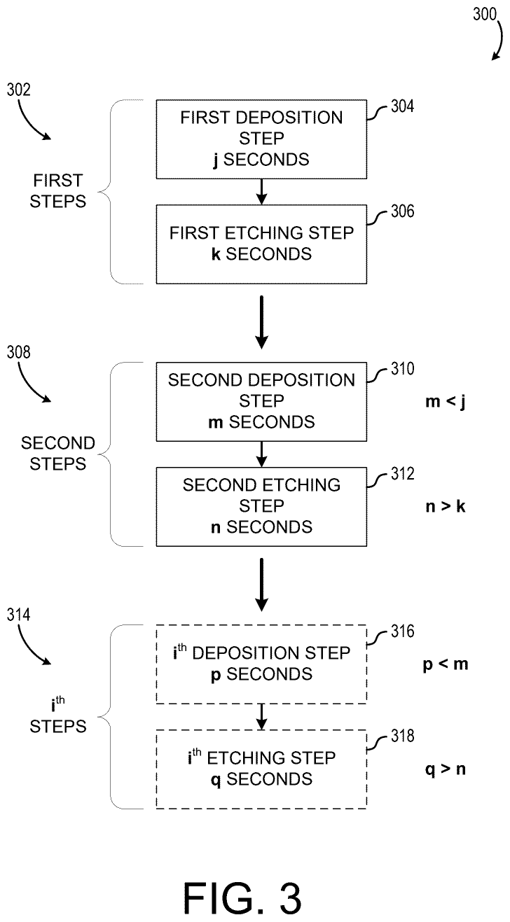

Continuing, a second deposition step 140 is performed after first etching step 130. As shown in FIG. 1D, second deposition step 140 results in additional growth of silicon-containing film 122. In some examples, second deposition step 140 can be performed using similar processing conditions as the first deposition step 120. In other examples, second deposition step 140 can be performed using different processing conditions than first deposition step 120. For example, a duration of second deposition step 140 can be different from a duration of first deposition step 120. The varying of step durations is discussed in more detail below with regard to FIG. 3.

Silicon-containing film 122 also can comprise breadloaf structures 142 resulting formed during the second deposition step 140. However, as mentioned above, the growth of silicon-containing film 122 can be inhibited by adsorbed halogen-containing etchant on sidewalls of pillars 102, 103, 104. Thus, the breadloaf structures 142 are farther from substrate 100 compared to the breadloaf structures depicted in FIG. 1B.

Next, a second etching step 150 is performed. In some examples, the second etching step 150 can be performed using similar processing conditions as the first etching step 130. In other examples, the second etching step 150 can be performed using different processing conditions as the first etching step 130. For example, a duration of second etching step 150 can be different from first etching step 130. Step durations are discussed in more detail below with regard to FIG. 3. As shown in FIG. 1E, the second etching step can etch the breadloaf structures 142. As a result, silicon-containing film 122 is thicker on the top fields of pillars 102, 103, 104 compared to the sidewalls. In some examples, sidewalls can be substantially free of silicon-containing film 122.

FIG. 1F shows substrate 100 following a third deposition step 160. Third deposition step 160 can be performed using similar processing conditions as the first and/or second deposition steps, or different processing conditions. Finally, FIG. 1G shows substrate 100 following a third etching step 170. Third etching step 170 can be performed using similar processing conditions as the first and/or second etching steps, or different processing conditions. As a result of alternating deposition steps and etching steps, the silicon-containing film 122 comprises a vertical growth profile.

As discussed above, the duration of deposition steps and etching steps can vary during the cyclic CVD/etching process. FIG. 3 shows a flow diagram for an example cyclic CVD/etching process 300 that includes adjusting step durations while performing alternating deposition steps and etching steps. Cyclic CVD/etching process 300 includes decreasing deposition step durations and increasing etching step durations. This can help achieve a vertical growth profile of a deposited film. For example, as the silicon-containing film grows vertically, the volume of gaps between spaced structures increases. Due to increased gap volume, concentrations of gases can be relatively lower. As a result, film growth rates on sidewall surfaces can decrease relative to film growth rates on top fields. Similarly, additional etching step durations can allow etchants to diffuse to the bottom of a gap. As such, adjustments to deposition step durations and etching step durations can help deposit a silicon-containing film with a vertical growth profile.

Cyclic CVD/etching process 300 comprises first cycle 302. First cycle 302 comprises a first deposition step 304 that is performed with a duration of j seconds. In some examples, 4≤j≤20. First cycle 302 further comprises a first etching step 306. In some examples, first etching step can be performed for a duration of k seconds where 2≤k≤10. In other examples, any other suitable durations can be used.

Next, the cyclic CVD/etching process 300 comprises second cycle 308. Second cycle 308 comprises a second deposition step 310 that is performed with a duration of m seconds where m<j. Second cycle 308 further comprises a second etching step 312 that is performed with a duration of n seconds where n>k. As such, the duration of the deposition step is decreased and the duration of the etching step is increased from first cycle 302 to second cycle 308.

Continuing, cyclic CVD/etching process 300 optionally comprises i^{th} cycle 314. The cyclic CVD/etching process 300 can comprise any suitable number of steps. The i^{th} cycle 314 comprises an i^{th} deposition step 316 that is performed with a duration of p seconds where p<m. The i^{th} cycle 314 further comprises an i^{th} etching step 318 that is performed with a duration of q seconds where q>n. As such, the duration of the deposition step is further decreased and the duration of the etching step is further increased from second cycle 308 to i^{th} cycle 314. In this manner, growth of the silicon-containing film on sidewalls of spaced structures can be inhibited to a greater degree in later steps of cyclic CVD/etching process 300. This can help achieve an improved vertical growth profile compared to examples with constant step durations.

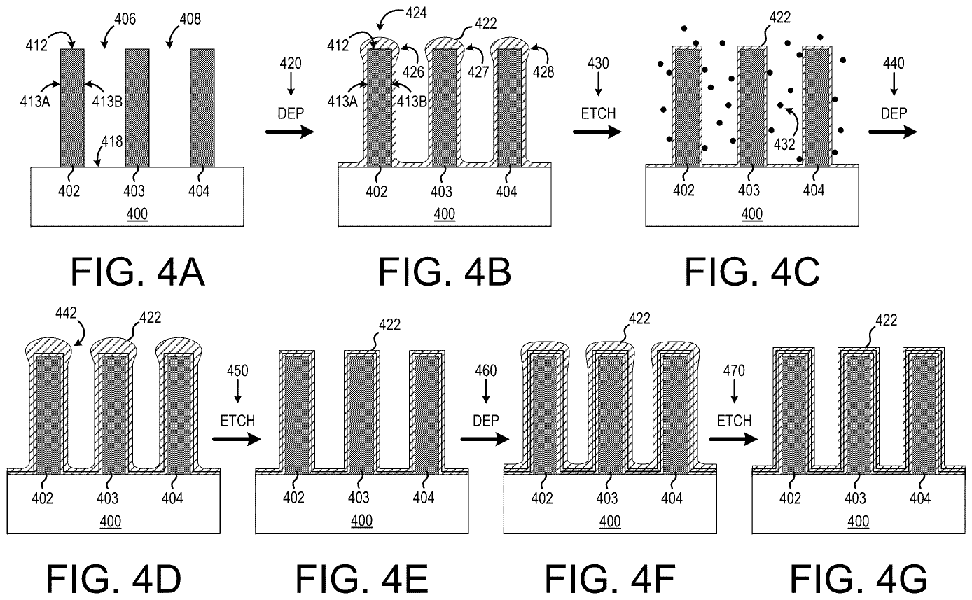

As discussed above, the processing conditions also can be controlled to grow the silicon-containing film conformally. FIGS. 4A-4G schematically show example structures formed during a cyclic CVD/etching process comprising alternating deposition steps and etching steps to deposit a conformal film onto spaced structures. The cyclic CVD/etching process can be performed in a processing chamber of a processing tool, for example. An example processing tool is described below with regard to FIG. 7.

As shown in FIG. 4A, substrate 400 comprises spaced structures comprising three pillars 402, 403, 404. A gap 406 is formed between pillar 402 and pillar 403. Another gap 408 is formed between pillar 403 and pillar 404. Each pillar comprises a top field and sidewalls. For example, pillar 402 comprises a top field 412 and sidewalls 413A, 413B. Further, a bottom field 418 is located at the bottom of gap 406 between pillars 402, 403. The silicon-containing film can be deposited conformally onto the pillars 402, 403, 404 by performing a cyclic CVD/etching process with alternating deposition steps and etching steps.

FIG. 4B shows substrate 400 following a first deposition step 420 to deposit a silicon-containing film 422. First deposition step 420 deposits a portion of silicon-containing film 422 onto top fields and sidewalls of the pillars 402, 403, 404. However, as indicated at 424, silicon-containing film 422 is thicker on top field 412 compared to sidewalls 413A, 413B. Further, the silicon-containing film 422 is thicker near the top of the sidewalls. This forms breadloaf structures 426, 427, 428 respectively on pillars 402, 403, 404.

First deposition step 420 can comprise forming a plasma using a gas mixture comprising a silicon-containing film precursor, nitrogen (N₂), ammonia (NH₃), and an inert gas. Such a gas mixture can be used to deposit a film of silicon nitride. As mentioned above, presence of hydrogen in a gas mixture can improve the stability of a deposited silicon nitride film. In contrast to first deposition step 120 that uses hydrogen gas, use of ammonia can avoid some of the inhibitive effects of hydrogen on sidewall surfaces. This can help grow the silicon-containing film 422 conformally on sidewalls. As mentioned above, in some examples, a different CVD process such as thermal CVD can be used to deposit the silicon-containing film.

Examples of silicon-containing film precursors include those listed above. In some examples, the silicon-containing film precursor comprises silane, which can provide cost savings compared to more expensive precursors used in some ALD processes.

Examples of suitable inert gases include argon, helium, neon, krypton, and xenon.

As mentioned above, in some examples, a silicon-containing film can include carbon. Examples of such silicon-containing films include silicon carbide, silicon oxycarbide and silicon oxycarbonitride. Examples of carbon-containing precursors for forming such films include those listed above. Oxygen-containing precursors for forming silicon oxide, silicon oxynitride, silicon oxycarbide, and silicon oxycarbonitride films can include molecular oxygen, water, hydrogen peroxide, and nitrogen oxides.

First deposition step 420 can comprise any suitable duration. In some examples, first deposition step 420 comprises a duration of 10-300 seconds. However, durations outside of this range also can be used. Gases can be flowed into the processing chamber for part or all of the deposition step duration. First deposition step 420 can be performed at any suitable substrate temperature and processing chamber pressure. Examples include temperatures of 50° C. to 650° C. and pressures of 4 Torr to 20 Torr. In contrast to first deposition step 120 used for vertical growth, first deposition step 420 utilizes a relatively higher pressure. The relatively higher pressure helps lessen directional sputtering of inert gas ions in the plasma. As a result, film growth on sidewall surfaces can be enhanced. This can help to grow the silicon-containing film 422 conformally.

In some examples, first deposition step 420 can utilize a pulsed plasma. Pulsing the plasma can help form ions with relatively less kinetic energy compared to continuous wave plasmas. As discussed above, relatively lower ion energies result in a greater distribution of ion impact angles on sidewall surfaces. As a result, a relatively greater amount of film-forming species deposit onto the sidewall surfaces compared to a continuous wave plasma. This helps grow a thicker silicon-containing film on sidewall surfaces. Additionally, lower ion energies can lower the sputtering effect of the plasma gases. Lowering the sputtering effect can allow more sidewall growth, which can helps deposit the silicon-containing film 422 conformally. Any suitable duty cycle can be used for pulsing the plasma. Example duty cycles include duty cycles of 5% to 50%. Further, any suitable radiofrequency power can be used to form the plasma. Examples include radiofrequency power of 50 W to 6500 W. Where a second frequency is used, radiofrequency power for the second frequency can be 0 to 6500 W. Example frequencies for the radiofrequency plasma include frequencies of 400 kHz, 13.56 MHz, 27 MHz, 60 MHz, and 90 MHz. As described above, the plasma can be capacitively coupled or inductively coupled, in various examples.

Flow control hardware can be used to control a flow rate and/or quantity of each gas flowing into the processing chamber. Flow rates can depend upon various factors such as pressure, temperature, and chamber size. In some examples, the first deposition step 420 uses 100-300 mL of silicon-containing precursor, 200-500 mL of NH₃, and 8-12 L of N₂ at 5 Torr. In other examples, quantities outside these ranges can be used. In some examples, the processing chamber is purged following first deposition step 420.

As mentioned above, breadloaf structures 426, 427, 428 are formed during the first deposition step 420. Thus, the cyclic CVD/etching process next comprises a first etching step 430. First etching step 430 comprises forming a plasma using a gas mixture comprising a halogen-containing etchant 432. The plasma modifies the profile of the silicon-containing film 422 by etching the breadloaf structures 426, 427, 428. During first etching step 430, reactive ions in the plasma preferentially adsorb to and etch upper sidewall surfaces and top fields. This is because reactive ions in the plasma have short life times and react prior to reaching deeper surfaces of gaps 406, 408. Thus, ion flux and etch rates are greater on breadloaf structures 426, 427, 428 compared to other surfaces. By preferentially etching surfaces where there is faster film growth, first etching step 430 helps increase the degree of conformality of silicon-containing film 422. Other portions of the silicon-containing film 422 also are etched. For example, some of the silicon-containing film 422 on the top fields and sidewalls of the pillars 402, 403, 404 are etched. As shown in FIG. 1C, the silicon-containing film 422 comprises a substantially uniform thickness on top fields and sidewalls of pillars 102, 103, 104. As a result, the silicon-containing film 422 comprises a conformal profile.

First etching step 430 can utilize any suitable halogen-containing etchant 432. Examples include fluorine-containing etchants, chlorine-containing etchants, and bromine-containing etchants, as described above.

First etching step 430 can be performed for any suitable duration. Examples include durations of 2 to 20 seconds. However, an etching step duration outside of this range also can be used. Flow control hardware can be used to control a flow rate and/or quantity of the halogen-containing etchant flowing into the processing chamber during first etching step 430. In some examples, first etching step 430 flows halogen-containing etchant 432 with a flow rate of 100-300 sccm. Additionally, an inert gas can be flowed at a rate of 5000-30000 sccm. In other examples, flow rates outside these ranges can be used. Further, the first etching step 430 can be performed at a pressure of 3 to 5 Torr. As such, the first etching step 430 can be performed at a lower pressure compared to the first deposition step 420.

After performing the etching process in first etching step 430, the processing chamber can be purged.

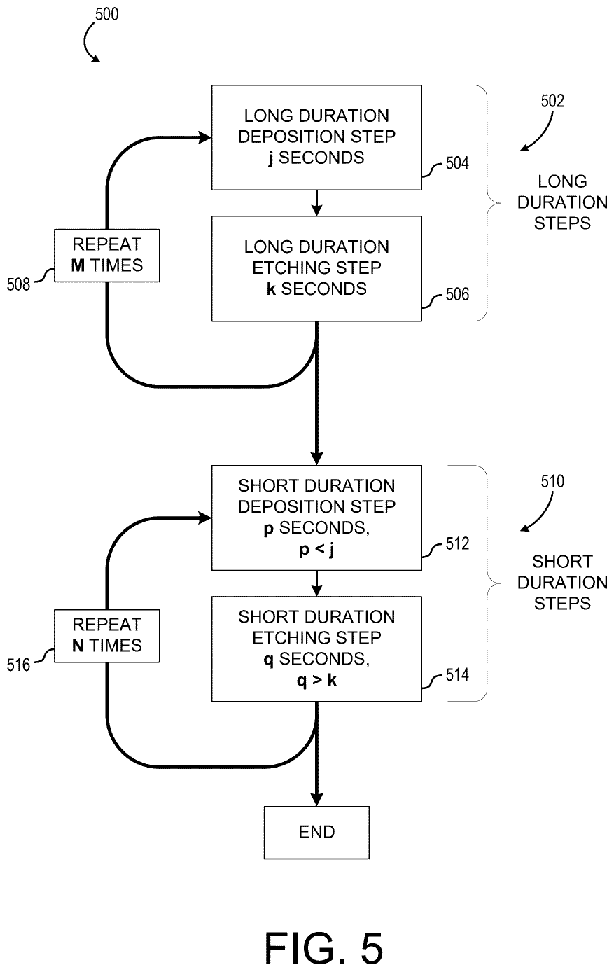

Continuing, a second deposition step 440 is performed after first etching step 430. As shown in FIG. 4D, second deposition step 440 results in additional growth of silicon-containing film 422. In some examples, second deposition step 440 can be performed using similar processing conditions as the first deposition step 420. In other examples, the second deposition step 440 can be performed using different processing conditions than first deposition step 420. For example, a duration of second deposition step 440 can be different from first deposition step 420. The varying of step durations is discussed in more detail below with regard to FIG. 5.

Silicon-containing film 422 also can comprise breadloaf structures 442 resulting formed during the second deposition step 440. However, the growth of silicon-containing film 422 can be inhibited by adsorbed halogen-containing etchant on sidewalls of pillars 402, 403, 404. Thus, the breadloaf structures 442 are farther from substrate 400 compared to the breadloaf structures depicted in FIG. 4B.

Next, a second etching step 450 is performed. Second etching step 450 can be performed using similar processing conditions as described above for first etching step 430. In other examples, the second etching step 450 can be performed using different processing conditions as the first etching step 430. For example, a duration of second etching step 450 can be different from first etching step 430. Step durations are discussed in more detail below with regard to FIG. 5. As shown in FIG. 4E, the second etching step can etch the breadloaf structures 442. As a result, the silicon-containing film 422 of FIG. 4E comprises a conformal film that is thicker compared to that of FIG. 4C.

FIG. 4F shows silicon-containing film 422 following a third deposition step 460. Third deposition step 460 can be performed using similar processing conditions as the first and/or second deposition steps, or different processing conditions. Finally, FIG. 4G shows silicon-containing film 422 following a third etching step 470. Third etching step 470 can be performed using similar processing conditions as the first and/or second etching steps, or different processing condition. In contrast to silicon-containing film 122, the silicon-containing film 422 is grown conformally. As a result, the silicon-containing film 422 of FIG. 4G comprises a conformal film that is thicker compared to that of FIG. 4E.

Thus, using the processing conditions described above, a silicon-containing film 422 can be grown comprising a conformal profile. In experiments, a deposition rate of 30 to 45 Å/min was achieved. The conformality of the film can be represented as a ratio of a film thickness on a sidewall of a spaced structure compared to a film thickness on a top field of the spaced structure. In experiments, a conformality of 100% to 150% was achieved, as measured by scanning transmission electron microscopy. In other examples, structures with profiles other than vertical growth or conformal can be formed by controlling processing conditions for cyclic CVD/etching.

As mentioned above, in some examples, deposition steps and etching steps can be performed with different durations in different cycles. In some examples, the cyclic CVD/etching process can comprise long duration steps in some cycles and short duration steps in other cycles. For example, the volume of gaps 406, 408 can decrease due to growth of the silicon-containing film 422. As such, depositing additional film layers conformally can be challenging. Thus, step durations can be adjusted to deposit a relatively thicker layer of silicon-containing film in earlier steps and a relatively thinner layer of silicon-containing film in later process steps. This can help grow a silicon-containing film conformally during later process steps. FIG. 5 shows a flow diagram for an example cyclic CVD/etching process 500 that includes adjusting step durations while performing alternating deposition steps and etching steps. Cyclic CVD/etching process 500 comprises first cycle 502. First cycle 502 comprises alternating first deposition steps 504 and first etching steps 506. In some examples, first deposition step 504 can be performed for a duration of j seconds where 120≤j≤240. In some examples, first etching step 506 can be performed for a duration of k seconds where 12≤k≤20. In other examples, any other suitable durations can be used. As indicated at 508, the first deposition steps 504 and first etching steps 506 can be repeated M times, where M≥1. In some more specific examples, 1≤M≤5.

After performing any suitable number M of first cycle 502, cyclic CVD/etching process 500 comprises performing second cycle 510. Second cycle 510 comprises alternating second deposition steps 512 and second etching steps 514. In some examples, second deposition step 512 can be performed for a duration of p seconds where 12≤p≤20. In some examples, second etching step 514 can be performed for a duration of q seconds where 2≤q≤10. In other examples, any other suitable durations can be used. Thus, each second deposition step 512 comprises a relatively shorter duration compared to first deposition step 504 described above. Similarly, each second etching step 514 comprises a relatively shorter duration compared to first etching step 506. As indicated at 516, the second deposition steps 512 and second etching steps 514 can be repeated N times, where N≥1. In some more specific examples, 2≤N≤10. By utilizing first cycle 502 followed by second cycle 510, cyclic CVD/etching process 500 can help deposit a silicon-containing film conformally when gaps shrink due to film growth.

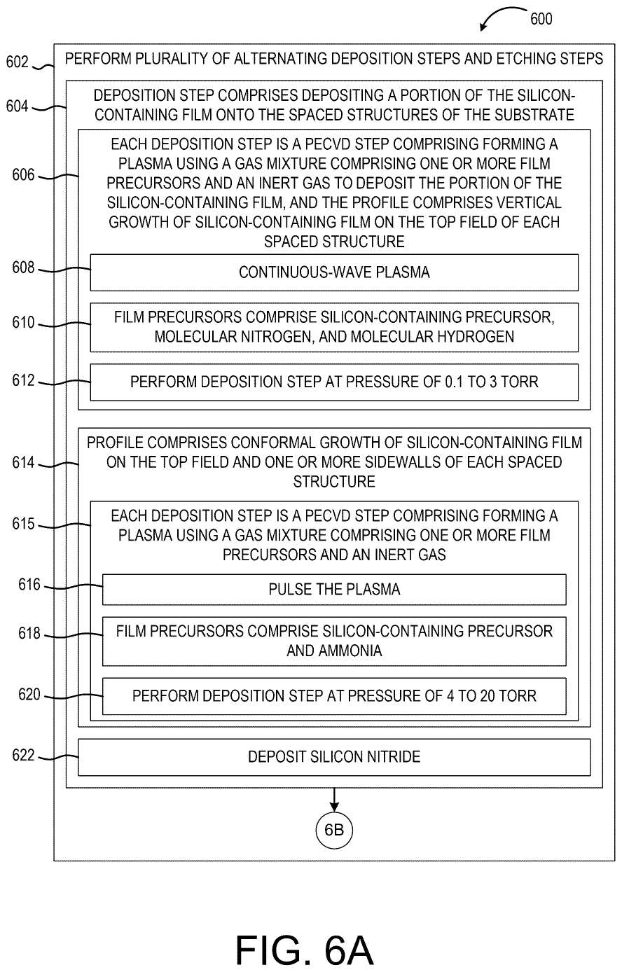

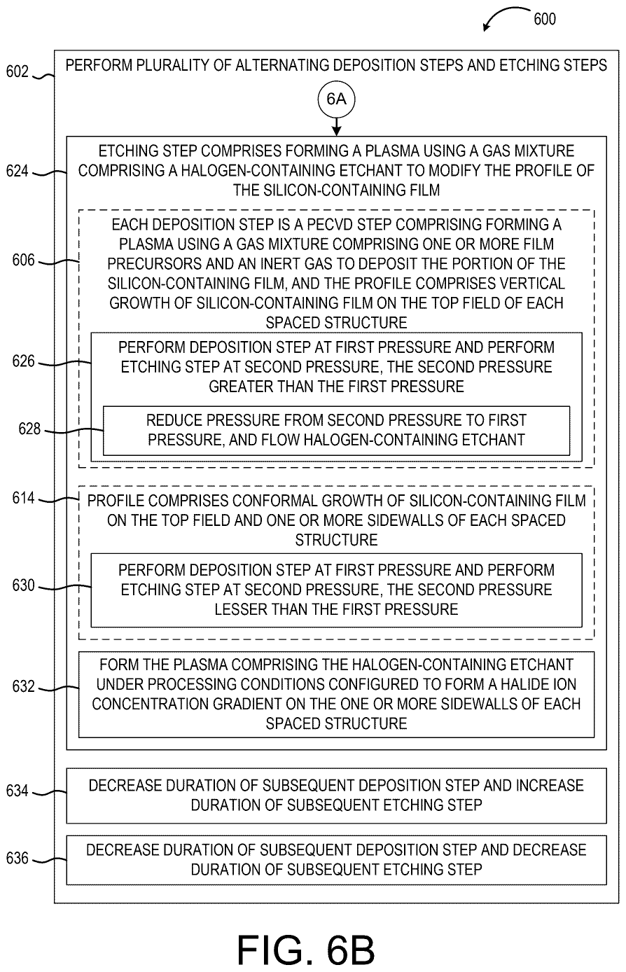

FIGS. 6A-6B shows a flow diagram for an example method 600 of a cyclic CVD/etching process to control a profile of a silicon-containing film deposited onto spaced structures of a substrate. Method 600 can be performed using a processing tool to process a substrate disposed within a processing chamber of the processing tool, for example.

Beginning with FIG. 6A, method 600 comprises performing a plurality of alternating deposition steps and etching steps at 602. At 604, a deposition step comprises depositing a portion of the silicon-containing film onto the spaced structures of the substrate.

In some examples, at 606, the deposition step comprises a PECVD step comprising forming a plasma using a gas mixture comprising one or more film precursors and an inert gas to deposit the portion of the silicon-containing film. The profile comprises vertical growth of the silicon-containing film on the top field of each spaced structure. In some such examples, the silicon-containing film is grown without horizontal growth on sidewalls of the spaced structures. In some examples, at 608, step 606 is performed using a continuous wave plasma. In other examples, a pulsed plasma can be used. In some examples, at 610, the one or more film precursors comprise a silicon-containing precursor, molecular nitrogen, and molecular hydrogen. Examples of suitable silicon-containing precursors are described above. Including hydrogen in the gas mixture helps to form a plasma with an enhanced etching effect on sidewalls. This slows the film growth rate on sidewall surfaces and helps achieve a vertical growth profile. In some examples, additional precursors can be used, such as carbon-containing precursors and oxygen-containing precursors. Examples include those listed above.

In some examples, at 612, the method 600 comprises performing the deposition step at a pressure of 0.1 to 3 Torr. As mentioned above, sputter etching effects from inert gas ions in the plasma can be increased at low pressure. This also helps slow the film growth rate on sidewall surfaces.

In other examples, instead of vertical growth, the profile comprises conformal growth of the silicon-containing film on the top field and one or more sidewalls of each spaced structure, at 614. In some examples, each deposition step is a thermal CVD step. In some examples, at 615, each deposition step is a PECVD step comprising forming a plasma using a gas mixture comprising one or more film precursors and an inert gas to deposit the portion of the silicon-containing film. In some such examples, at 616, method 600 comprises pulsing the plasma during the deposition step at 604. In some such examples, the plasma can be pulsed with a duty cycle of 5% to 50%, as mentioned above. As mentioned above, a pulsed plasma can help deposit a relatively thicker film on sidewalls surfaces. In some examples, at 618, the one or more film precursors comprise a silicon-containing precursor and ammonia. Use of ammonia helps lessen etching effects of hydrogen on film deposited on sidewall surfaces. Examples of suitable silicon-containing precursors include those described above. In some examples, at 620, method 600 comprises performing the deposition step at a pressure of 4 Torr to 20 Torr. In other examples, a pressure outside this range can be used. High pressure can decrease sputter etching effects of inert gas ions on sidewall surfaces. By lowering etching on sidewall surfaces at 616, 618, and/or 620, such examples can help provide a more even growth rate for the silicon-containing film on different surfaces of spaced structures, which helps provide for conformal growth.

In some examples, at 622, performing the deposition step at 604 comprises depositing silicon nitride. In other examples, the deposition step can comprise depositing a different silicon-containing film. Examples include silicon oxide, silicon carbides, silicon oxycarbides, silicon oxynitrides, silicon carbonitrides, and silicon oxycarbonitrides.

Continuing to FIG. 6B, at 624, the etching step comprises forming a plasma using a gas mixture comprising a halogen-containing etchant to modify the profile of the silicon-containing film. In some examples, a capacitively coupled plasma is used to help form halide ions from the halogen-containing etchant.

In examples that include step 606, method 600 comprises modifying the profile of the silicon-containing film to that of a vertical growth profile. In some such examples, at 626, method 600 comprises performing the deposition step at a first pressure and performing the etching step at a second pressure, the second pressure being greater than the first pressure. In some such examples, at 628, performing the etching step comprises reducing the pressure from the second pressure to the first pressure and flowing the halogen-containing etchant. In this manner, the halogen-containing etchant can inhibit film growth on sidewalls of the spaced structures during a subsequent deposition step.

In examples that include step 614, method 600 comprises modifying the profile of the silicon-containing film to that of conformal growth. In some such examples, at 630, method 600 comprises performing the deposition step at a first pressure and performing the etching step at a second pressure, the second pressure being less than the first pressure. As described above, performing the etching step at a relatively lower pressure than the deposition step can help achieve conformal growth.

In some examples, at 632, forming the plasma at 624 comprises forming the plasma under processing conditions configured to form a halide ion concentration gradient on the one or more sidewalls of each spaced structure. A concentration gradient can provide a relatively greater inhibition effect to film growth on surfaces near a top of a spaced structure compared to surfaces near a bottom of the spaced structure. In this manner, the halide ion concentration gradient can help lessen breadloafing.

Continuing, in some examples, at 634, performing the plurality of alternating deposition steps and etching steps at 602 comprises decreasing a duration of a subsequent deposition step and increasing a duration of a subsequent etching step. FIG. 3 shows an example where a duration of a subsequent deposition step is decreased and a duration of a subsequent etching step is increased. In some other examples, at 636, performing the plurality of alternating deposition steps and etching steps at 602 comprises decreasing a duration of a subsequent deposition step and decreasing a duration of a subsequent etching step. FIG. 5 shows an example where first steps are followed by second steps, the second steps comprising a shorter duration than the first steps.

FIG. 7 schematically shows an example processing tool 700 that can implement the examples described above with reference to FIGS. 1A-6B.

Processing tool 700 comprises a processing chamber 702 and a substrate support 704 within the processing chamber. The substrate support 704 is configured to support a substrate 706 disposed within the processing chamber 702. The substrate support 704 can comprise a pedestal, a chuck, and/or any other suitable structure. The substrate support 704 comprises a substrate heater 708. In other examples, a heater can be omitted, or can be located elsewhere within processing chamber 702.

The processing tool 700 further comprises a showerhead 710. In other examples, a processing tool can comprise a nozzle or other apparatus for introducing gas into processing chamber 702, as opposed to or in addition to a showerhead. The processing tool 700 further comprises flow control hardware 712. The flow control hardware 712 connects processing gas source(s) to the processing chamber. In the depicted example, the flow control hardware 712 connects a silicon-containing film precursor source 716, optionally a nitrogen-containing precursor source 718, optionally a hydrogen source 720, an inert gas source 722, and an etchant chemical source 724 to the processing chamber.

The silicon-containing film precursor source 716 comprises any suitable precursor chemical(s) for forming a silicon-containing film. Examples silicon-containing films include films comprising silicon nitride, silicon oxide, silicon carbide, silicon oxycarbides, and silicon oxynitrides. Examples of silicon-containing film precursors include those listed above. In some examples, a film precursor source can comprise a mixture of chemicals. In other examples, two or more separate film precursor sources can be used to provide a respective two or more film precursors.

Optionally, a carbon-containing precursor source (not shown) can be used to provide a carbon-containing precursor for forming a silicon carbide film. Example carbon-containing precursors include those listed above. Further, in some examples, an optional oxygen-containing precursor source can be used to provide an oxygen-containing precursor for forming silicon oxide, silicon oxynitride, silicon oxycarbide, or silicon oxycarbonitride films. Examples of oxygen-containing precursors can include molecular oxygen, water, hydrogen peroxide, and nitrogen oxides.

Nitrogen-containing precursor source 718 comprises any suitable nitrogen-containing precursor. In some examples, nitrogen-containing precursor source 718 comprises NH₃. In some examples, the nitrogen-containing precursor source 718 comprises N₂. In some examples, a combination of NH₃ and N₂ can be used. An example precursor for providing nitrogen for formation of a silicon oxynitride film is N₂O. When included, hydrogen source 720 comprises molecular hydrogen (H₂). As described above, including H₂ in a PECVD gas mixture can increase etching effects on sidewall surfaces of spaced structures and help grow a silicon-containing film with vertical growth. Alternatively, omitting H₂ can help grow a film conformally.

The inert gas source 722 can comprise any suitable inert gas. Examples include argon, helium, neon, krypton, and xenon.

The etchant chemical source 724 can comprise any suitable halogen-containing etchant chemical. Examples include fluorine-containing etchants, chlorine-containing etchants, and bromine-containing etchants. Example fluorine-containing etchants can include F₂, HF, BF₃, PF₃, NF₃, a chlorofluorocarbon, a fluorocarbon, a hydrofluorocarbon, a chalcogen fluoride such as SF₄ or SF₆, or an interhalogen such as ClF₃ or ClF₅. Example fluorocarbons include CF₄ and C₂F₆. Examples of chlorine-containing etchants include HCl, Cl₂, and chalcogen chlorides such as S₂Cl₂ or SCl₂. Examples of bromine-containing etchants include HBr and Br₂.

The flow control hardware 712 can include any suitable components. Examples include mass flow controllers, valves, and conduits. For example, the flow control hardware 712 can comprise one or more valves controllable to place a selected gas source or selected gas sources in fluid connection with showerhead 710. The flow control hardware 712 also can comprise one or more mass flow controllers or other controllers for controlling a mass flow rate of gas.

The processing tool 700 further comprises an exhaust system 732. The exhaust system 732 is configured to exhaust gases from the processing chamber 702. The exhaust system 732 can comprise any suitable hardware, including one or more low vacuum pumps and one or more high vacuum pumps. Together, flow control hardware 712 and exhaust system 732 can be operated to achieve a selected pressure in processing chamber 702 during substrate processing.

The processing tool 700 further comprises a radiofrequency power source 734 that is electrically connected to showerhead 710. Radiofrequency power source 734 is configured to form a plasma using a gas mixture. For example, during a deposition step, radiofrequency power source 734 can be operated to form a plasma using a gas mixture comprising one or more film precursors and an inert gas to deposit a silicon-containing film. Additionally, during an etching step, radiofrequency power source 734 can be operated to form a plasma using a gas mixture comprising a halogen-containing etchant to etch the silicon-containing film. The substrate support 704 is configured as a grounded opposing electrode in this example. In other examples, the radiofrequency power source 734 can supply radiofrequency power to substrate support 704, or to another suitable electrode structure. Thus, the radiofrequency power source 734 forms a capacitively coupled plasma (CCP) when operated. Further, the radiofrequency power source 734 can be operated to pulse the plasma, for example, using any suitable duty cycle. Alternatively, the radiofrequency power source 734 can form a continuous wave plasma.

The processing tool 700 further includes include a matching network 736 for impedance matching of the radiofrequency power source 734. The radiofrequency power source 734 can be configured to provide RF energy of any suitable frequency and power. Examples frequencies include 400 kHz, 13.56 MHz, 27 MHz, 60 MHz, and 90 MHz. In some examples, the radiofrequency power source 734 is configured to operate at a plurality of different frequencies and/or powers. For example, as described above, a plasma can comprise a low frequency (LF) radiofrequency energy component and a high frequency (HF) radiofrequency energy component Examples of frequencies for the LF power component can include frequencies of 3 MHz and below. The LF energy component can comprise a power of 0-6500 W in some examples. Examples of suitable high-frequency RF power includes frequencies of 3 MHz to 300 MHz. The HF radiofrequency energy component can comprise a power of 50-6500 W in some examples.

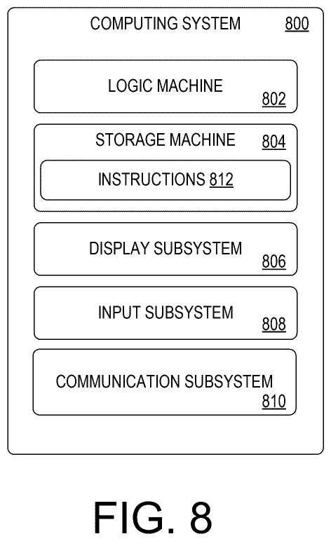

The processing tool 700 further comprises a controller 750 configured to control operation of the processing tool. The controller 750 is operatively coupled to the substrate heater 708, the flow control hardware 712, the exhaust system 732, and the radiofrequency power source 734. The controller 750 is configured to control various functions of processing tool 700 to perform a CVD/etching cycle including deposition steps and etching steps. For example, the controller 750 is configured to operate the substrate heater 708 to heat a substrate to a desired temperature. The controller 750 also is configured to operate the flow control hardware 712 to flow a selected gas or mixture of gases at a selected rate into the processing chamber 702. The controller 750 is further configured to operate the exhaust system 732 to remove gases from processing chamber 702. The controller 750 can, for example, control the exhaust system 732 and/or the flow control hardware 712 to purge the processing chamber 702. The controller 750 is configured to operate the radiofrequency power source 734 to form a plasma, as well as to control any other suitable functions of processing tool 700. The controller 750 can comprise any suitable computing system. Example computing systems are described below with reference to FIG. 8.

FIG. 8 schematically shows a non-limiting example of a computing system 800 that can enact one or more of the methods and processes described above. Computing system 800 is shown in simplified form. Computing system 800 may take the form of one or more personal computers, workstations, computers integrated with substrate processing tools, and/or network accessible server computers.

Computing system 800 includes a logic machine 802 and a storage machine 804. Computing system 800 may optionally include a display subsystem 806, input subsystem 808, communication subsystem 810, and/or other components not shown in FIG. 8. Controller 750 is an example of computing system 800.

Logic machine 802 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 804 includes one or more physical devices configured to hold instructions 812 executable by the logic machine to implement the methods and processes described herein. When such methods and processes are implemented, the state of storage machine 804 may be transformed—e.g., to hold different data.

Storage machine 804 may include removable and/or built-in devices. Storage machine 804 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 804 may include volatile, nonvolatile, dynamic, static, read/write, read-only, random-access, sequential-access, location-addressable, file-addressable, and/or content-addressable devices.

It will be appreciated that storage machine 804 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 802 and storage machine 804 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 806 may be used to present a visual representation of data held by storage machine 804. This visual representation may take the form of a graphical user interface (GUI). As the herein described methods and processes change the data held by the storage machine, and thus transform the state of the storage machine, the state of display subsystem 806 may likewise be transformed to visually represent changes in the underlying data. Display subsystem 806 may include one or more display devices utilizing virtually any type of technology. Such display devices may be combined with logic machine 802 and/or storage machine 804 in a shared enclosure, or such display devices may be peripheral display devices.

When included, input subsystem 808 may comprise or interface with one or more user-input devices such as a keyboard, mouse, or touch screen. In some examples, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 810 may be configured to communicatively couple computing system 800 with one or more other computing devices. Communication subsystem 810 may include wired and/or wireless communication devices compatible with one or more different communication protocols. As non-limiting examples, the communication subsystem may be configured for communication via a wireless telephone network, or a wired or wireless local- or wide-area network. In some examples, the communication subsystem may allow computing system 800 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of performing a cyclic chemical vapor deposition (CVD)/etching process to control a profile of a silicon-containing film deposited onto a substrate comprising spaced structures, each spaced structure comprising a top field and one or more sidewalls, the method comprising:
performing a plurality of alternating CVD steps and etching steps,
each CVD step comprising depositing a portion of the silicon-containing film onto the spaced structures of the substrate, and
each etching step comprising forming a plasma using a gas mixture comprising a halogen-containing etchant to modify the profile of the silicon-containing film.

2. The method of claim 1, wherein each CVD step is a plasma-enhanced CVD (PECVD) step comprising forming a plasma using a gas mixture comprising one or more film precursors and an inert gas to deposit the portion of the silicon-containing film, and wherein the profile comprises vertical growth of the silicon-containing film on the top field of each spaced structure.

3. The method of claim 2, wherein forming the plasma comprising the one or more film precursors comprises forming a continuous wave plasma.

4. The method of claim 2, wherein the one or more film precursors comprises a silicon-containing precursor, molecular nitrogen, and molecular hydrogen.

5. The method of claim 2, wherein each PECVD step is performed at a first pressure of 0.1 to 3 Torr and each etching step is performed at a second pressure, the second pressure being greater than the first pressure.

6. The method of claim 5, wherein each etching step further comprises reducing a pressure from the second pressure to the first pressure, and flowing the halogen-containing etchant while reducing the pressure.

7. The method of claim 1, wherein the controlled profile comprises conformal growth on the top field and the one or more sidewalls of each spaced structure.

8. The method of claim 7, wherein each CVD step is a PECVD step comprising forming a plasma using a gas mixture comprising one or more film precursors and an inert gas to deposit the portion of the silicon-containing film.

9. The method of claim 8, wherein forming the plasma comprising the one or more film precursors comprises pulsing the plasma.

10. The method of claim 8, wherein the one or more film precursors comprises a silicon-containing precursor and ammonia.

11. The method of claim 8, wherein each PECVD step is performed at a first pressure of 4 Torr to 20 Torr and each etching step is performed at a second pressure, the second pressure being equal to or lesser than the first pressure.

12. The method of claim 1, wherein the silicon-containing film comprises silicon nitride.

13. The method of claim 1, wherein the silicon-containing film comprises one of silicon oxide, silicon oxynitride, silicon carbide, silicon oxycarbide, silicon carbonitride, or silicon oxycarbonitride.

14. A plasma enhanced chemical vapor deposition (PECVD) tool, comprising:
a processing chamber;
a substrate support disposed in the processing chamber;
a radiofrequency power source configured to supply radiofrequency power to form a plasma in the processing chamber;
flow control hardware configured to control flow of gas from a film precursor source, an inert gas source, and an etchant chemical source into the processing chamber; and
a controller configured to perform a plurality of alternating deposition steps and etching steps, the controller configured to
in a deposition step,
operate the flow control hardware to flow silicon-containing film precursor from the film precursor source and inert gas from the inert gas source into the processing chamber, and
operate the radiofrequency power source to form a plasma comprising the silicon-containing film precursor and the inert gas under conditions configured to deposit a silicon-containing film onto spaced structures of a substrate supported by the substrate support, each spaced structure comprising a top field and one or more sidewalls; and
in an etching step,
operate the flow control hardware to flow a halogen-containing etchant chemical from the etchant chemical source into the processing chamber, and
operate the radiofrequency power source to form a plasma comprising the halogen-containing etchant chemical under conditions configured to etch the silicon-containing film.

15. The PECVD tool of claim 14, wherein the controller is configured to perform an etching step using one or more of a longer duration or a greater partial pressure of the halogen-containing etchant in comparison to an etching step performed previously in the plurality of etching steps.

16. The PECVD tool of claim 14, wherein the controller is configured to, during deposition steps, operate the flow control hardware and an exhaust system of the PECVD tool to maintain a pressure in 0.1 to 3 Torr, and operate the radiofrequency power source to form a continuous wave plasma to deposit the silicon-containing film with vertical growth on top fields of the spaced structures.

17. A method of performing plasma-enhanced chemical vapor deposition (PECVD) to control vertical growth of a silicon-containing film deposited onto a substrate comprising spaced structures, each spaced structure comprising a top field and one or more sidewalls, the method comprising:
performing a plurality of alternating deposition steps and etching steps to deposit the silicon-containing film onto the spaced structures of the substrate,
each deposition step comprising forming a plasma using a gas mixture comprising a silicon-containing film precursor, a nitrogen-containing film precursor, hydrogen gas, and an inert gas to deposit the silicon-containing film onto the spaced structure, and
each etching step comprising forming a plasma using a gas mixture comprising a halogen-containing etchant to etch the silicon-containing film, thereby growing the silicon-containing film on the top field of each spaced structure at a growth rate that is faster than a growth rate of the silicon-containing film on the one or more sidewalls of each spaced structure.

18. The method of claim 17, further comprising decreasing a duration of subsequent deposition steps and increasing a duration of subsequent etching steps while performing the plurality of alternating deposition steps and etching steps.

19. The method of claim 17, wherein each deposition step is performed at a first pressure and each etching step is performed at a second pressure, the second pressure being greater than the first pressure, and each etching step further comprises flowing the halogen-containing etchant while reducing a pressure from the second pressure to the first pressure.

20. The method of claim 17, wherein forming the plasma in a subsequent deposition step of the plurality of deposition steps comprises forming a plasma further comprising residual halogen-containing etchant from a prior etching step.
